(19) United States
(12) Patent Application Publication
(10) Pub. No.: US 2012/0106050 A1
(43) Pub. Date: May 3, 2012

(54) PORTABLE ELECTRONIC APPARATUS

(75) Inventors: Kenjiro OKAMOTO, Osaka (JP); Keisuke NONAKA, Osaka (JP); Hong Cheol KIM, Osaka (JP)

(73) Assignee: KYOCERA CORPORATION, Kyoto (JP)

(21) Appl. No.: 13/282,442

(22) Filed: Oct. 26, 2011

(30) Foreign Application Priority Data
Oct. 27, 2010 (JP) 2010-240730

(51) Int. Cl. H05K 5/00

(52) U.S. Cl. 361/679.01

(57) ABSTRACT

A portable electronic apparatus includes a first casing having a display surface in its surface, a second casing having a display surface in its surface, a coupling mechanism adapted to couple the first casing and the second casing to each other to take at least two states which are a closed state where the display surface in the first casing is covered with a rear surface of the second casing and also the display surface in the second casing is exposed, and an open state where the second casing has been moved with respect to the first casing from the closed state, and the display surfaces in both the casings are exposed in the same plane.

### CROSS-REFERENCE TO RELATED APPLICATIONS

This application claims priority from Japanese Patent Application No. 2010/240730 filed on Oct. 27, 2010, which is hereby incorporated by reference.

### BACKGROUND OF THE INVENTION

1. Field of the Invention

The present invention relates to portable electronic apparatuses constituted by a pair of casings coupled to each other.

2. Background Art

Conventionally, there have been known portable electronic apparatuses constituted by a pair of casings coupled to each other, such that both the casings are provided with respective display surfaces, thereby enabling both the display surfaces to offer larger amounts of information to users.

Such portable electronic apparatuses are adapted, for example, to allow both the casings to move with respect to each other, between a single-surface exposed state (a closed state) where the pair of casings are overlaid on each other, the lower casing (a first casing) is covered at its display surface (a first display surface) with the upper casing (a second casing), and only the display surface (a second display surface) in the second casing is exposed, and a double-surface exposed state where the second casing has been moved with respect to the first casing, and the display surfaces of both the casings are exposed.

In the double-surface exposed state, the second casing has been brought into an open state where the second display surface is flushed with the first display surface in the same plane.

With the portable electronic apparatus, in the open state, the display surface in the first casing and the display surface in the second casing are flushed with each other in the same plane, which enables displaying images on the two display surfaces serving as a single large screen.

In this case, by placing a display in each casing such that it is as close to the other casing as possible in the open state, the display surfaces in the two casings are made as close to each other as possible in the open state, which enables eliminating large discontinuities in images displayed on the two display surfaces.

However, with such a structure for placing a display in each casing such that the display is as close to the other casing as possible in the open state, light transparent plates such as glass plates which cover the surfaces of the displays are placed in the vicinity of the front end surfaces of the casings. Accordingly, if a large impulsive force acts on the front end surfaces of the casings, due to falling of the apparatus onto a floor surface or the like, this impulsive force may be exerted as a large external force on the end surfaces of the light transparent plates, thereby inducing fractures of the light transparent plates.

Therefore, it is an object of the present invention to provide a portable electronic apparatus capable of effectively alleviating impulsive forces acting on the surfaces of the displays.

### SUMMARY OF THE INVENTION

A portable electronic apparatus according to the present invention includes a first casing having a first display in its surface; a second casing having a second display in its surface; and a coupling mechanism adapted to couple the first casing and the second casing to each other to take at least two states which are a closed state where the first display in the first casing is covered with a rear surface of the second casing and, also, the second display in the second casing is exposed, and an open state where the second casing has been moved from the closed state so that the displays in both the casings are exposed in the same plane; wherein the second casing is provided with at least a single convex portion which faces the first casing in the open state and, also, protrudes forwardly from a front end surface of the first casing in the closed state, on its front end surface which aligns with the front end surface of the first casing in the closed state.

### BRIEF DESCRIPTION OF THE DRAWINGS

FIG. 1 is a perspective view illustrating a portable electronic apparatus according to an embodiment of the present invention, in a closed state;

FIG. 2 is a perspective view illustrating the portable electronic apparatus in the closed state with being reversed;

FIG. 3 is a perspective view illustrating the portable electronic apparatus, in a tilt state;

FIG. 4 is a perspective view illustrating the portable electronic apparatus, in the tilt state, when viewed at its rear side;

FIG. 5 is a perspective view illustrating the portable electronic apparatus in a first open state;

FIG. 6 is a perspective view illustrating the portable electronic apparatus in the first open state with being reversed;

FIG. 7 is a perspective view illustrating the portable electronic apparatus in a second open state;

FIG. 8 is a perspective view illustrating the portable electronic apparatus in the second open state with being reversed;

FIG. 9 is an exploded perspective view illustrating the portable electronic apparatus;

FIG. 10 is an exploded perspective view illustrating the portable electronic apparatus with being reversed;

FIG. 11 is a perspective view illustrating the portable electronic apparatus, wherein a portion thereof is further exploded from the state of FIG. 10;

FIG. 12 is a perspective view illustrating the portable electronic apparatus, wherein a portion thereof is further exploded from the state of FIG. 11;

FIG. 13 is a cross-sectional view illustrating the portable electronic apparatus;

FIG. 14 is a perspective view illustrating the portable electronic apparatus, wherein a portion thereof is further exploded from the state of FIG. 8;

FIGS. 15A and B are another cross-sectional views illustrating the portable electronic apparatus, illustrating a transition from the first open state A to the second open state B;

FIGS. 16A and B are cross-sectional views illustrating the portable electronic apparatus, by enlarging the portion C and the portion D in FIG. 15;

FIGS. 17A to C are cross-sectional views illustrating states of deformations of a flexible lead during processing for transitions from the closed state A to the second open state C through the first open state B;

FIG. 18 is a perspective view illustrating a pair of convex portions formed in the second casing in the closed state;

FIG. 19 is a perspective view illustrating the portion E in FIG. 18 in an enlarging manner;

FIG. 20 is a plan view illustrating the pair of convex portions formed in the second casing in the closed state;

FIG. 21 is a plan view illustrating the portion F in FIG. 20 in an enlarging manner;

FIG. 22 is an enlarged cross-sectional view illustrating main portions of the second casing at the position where a convex portion is formed;

FIGS. 23A to D are a series of side views illustrating the first half of processing for transitions of the portable electronic apparatus according to the present invention from the closed state to the second open state through the tilt state;

FIGS. 24A to D are a series of side views illustrating the second half of the same processing; and

FIGS. 25A and B are side views illustrating the portable electronic apparatus according to the present invention being placed on a desk, in the tilt state A and in the second open state B.

### DETAILED DESCRIPTION OF EMBODIMENTS

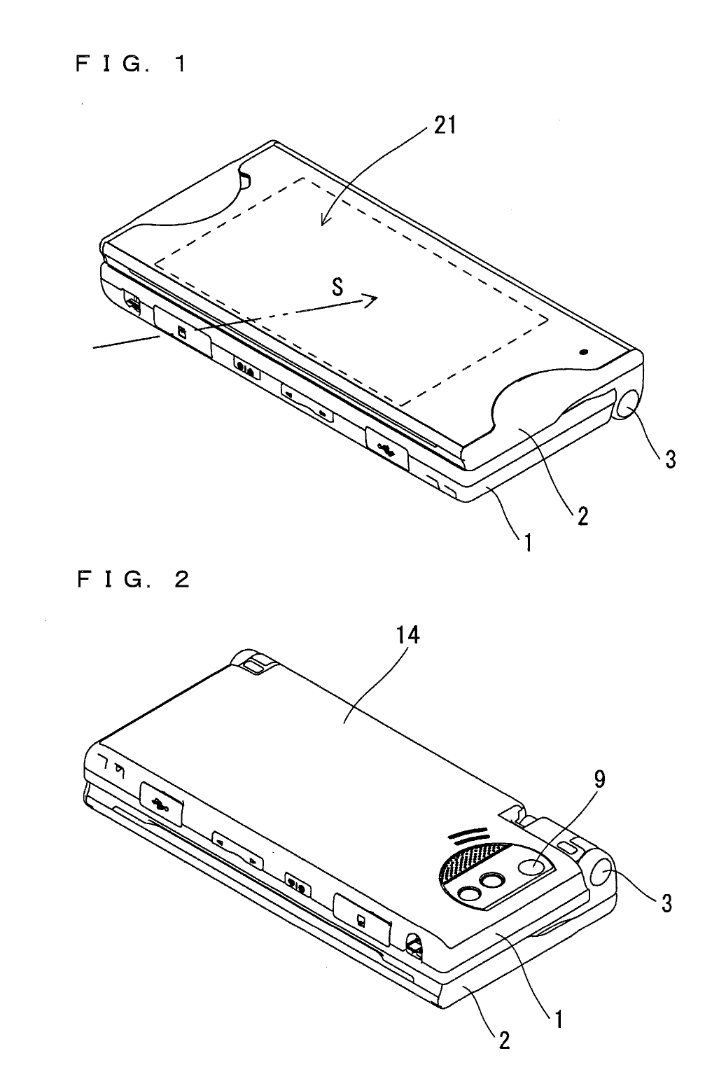

A portable electronic apparatus according to an embodiment of the present invention includes a first casing 1 having a first display surface 11 in its surface, a second casing 2 having a second display surface 21 in its surface, and a coupling mechanism 3 which couples the first casing 1 and the second casing 2 to each other, as illustrated in FIGS. 1 to 8.

Further, the first display surface 11 and the second display surface 21 are capable of displaying, thereon, characters or videos, as well as images.

As illustrated in FIG. 2, a photographing lens 9 is provided in the rear surface of the first casing 1.

Further, for identifying respective portions of the components of the portable electronic apparatus in the following description, “front (the side closer to the person viewing the figures)”, “rear”, “left” and “right” regarding the portable electronic apparatus illustrated in FIG. 1 when viewed along a user's line of sight indicated by an arrow S in the figure will be also referred to as “front”, “rear”, “left” and “right”, regardless of the attitude of the portable electronic apparatus in the other drawings.

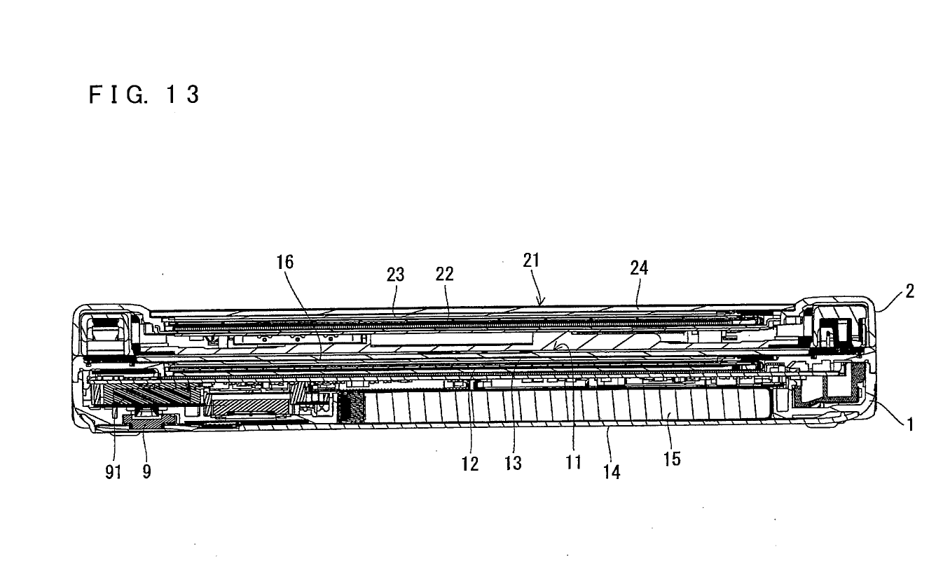

As illustrated in FIG. 13, inside the first casing 1, there are placed a first touch panel 13 and a first display 12 such that they face the first display surface 11, and, further, there is placed a camera 91 such that it faces the photographing lens 9. Further, the first casing 1 houses, therein, a battery 15, such that replacement of the battery 15 can be performed, by removing a battery lid 14.

On the other hand, inside the second casing 2, there are placed a second touch panel 23 and a second display 22, such that they face the second display surface 21.

On the surface of the first touch panel 13, there is placed a glass plate 16 which is wider than the first display 12 and the first touch panel 13, and the glass plate 16 forms, at its surface, the first display surface 11 to display, thereon, images in the first display 12.

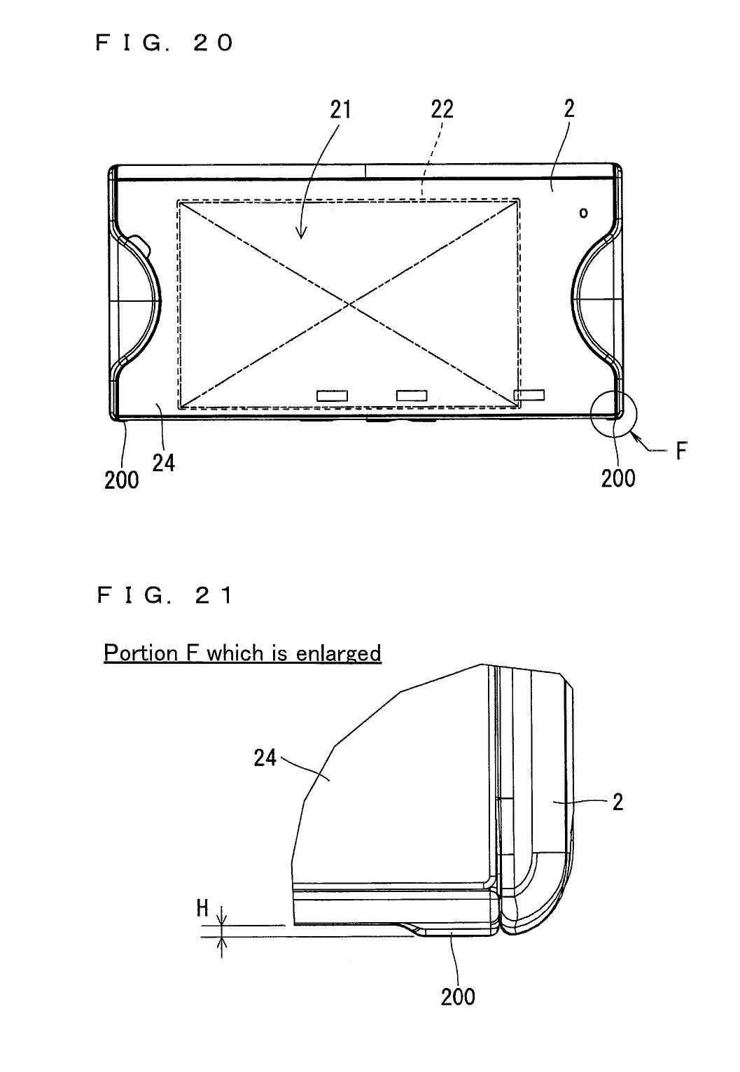

Further, on the surface of the second touch panel 23, there is placed a glass plate 24 which is wider than the second display 22 and the touch panel 23, and the glass plate 24 forms, at its surface, the second display surface 21 to display, thereon, images in the second display 22 (see FIG. 20).

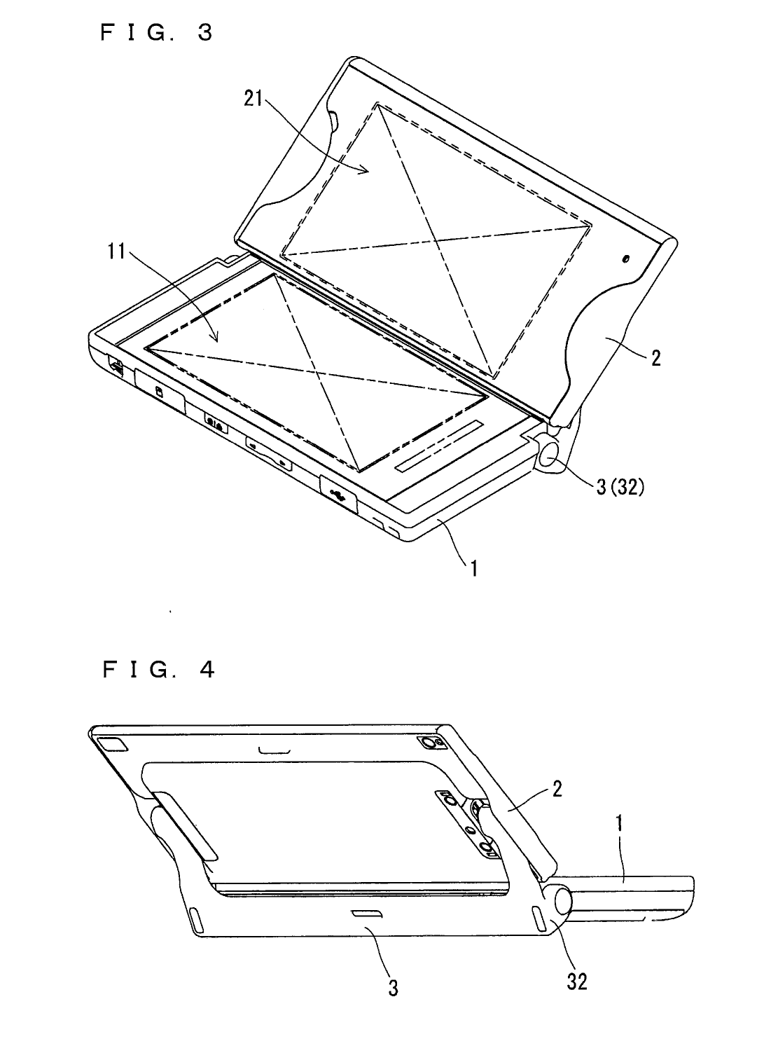

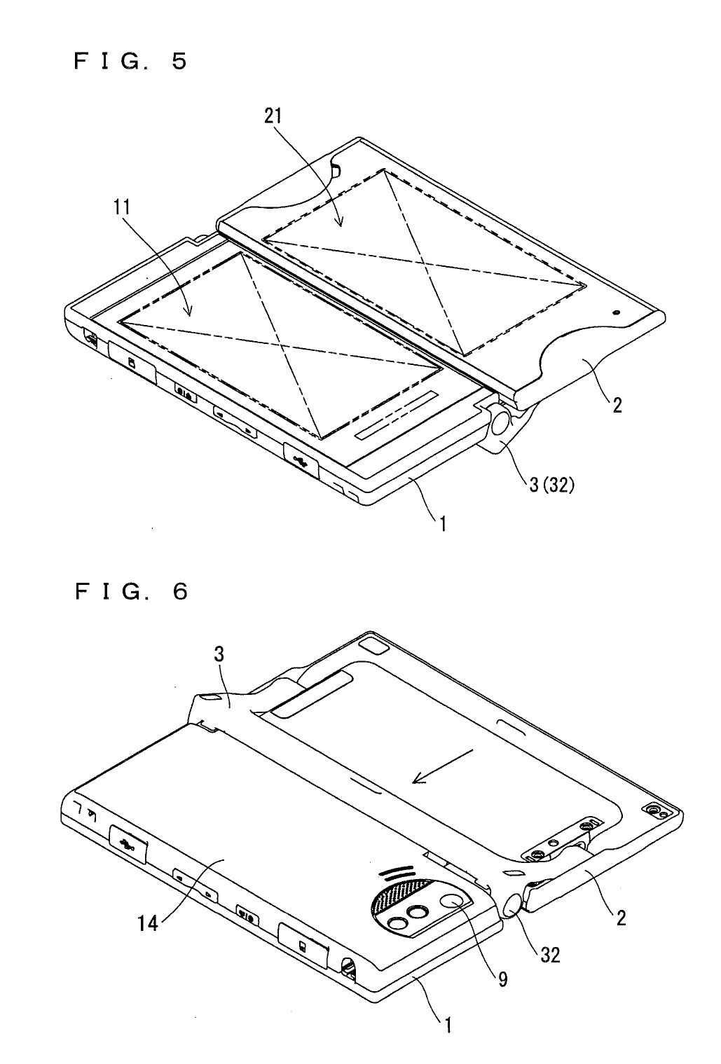

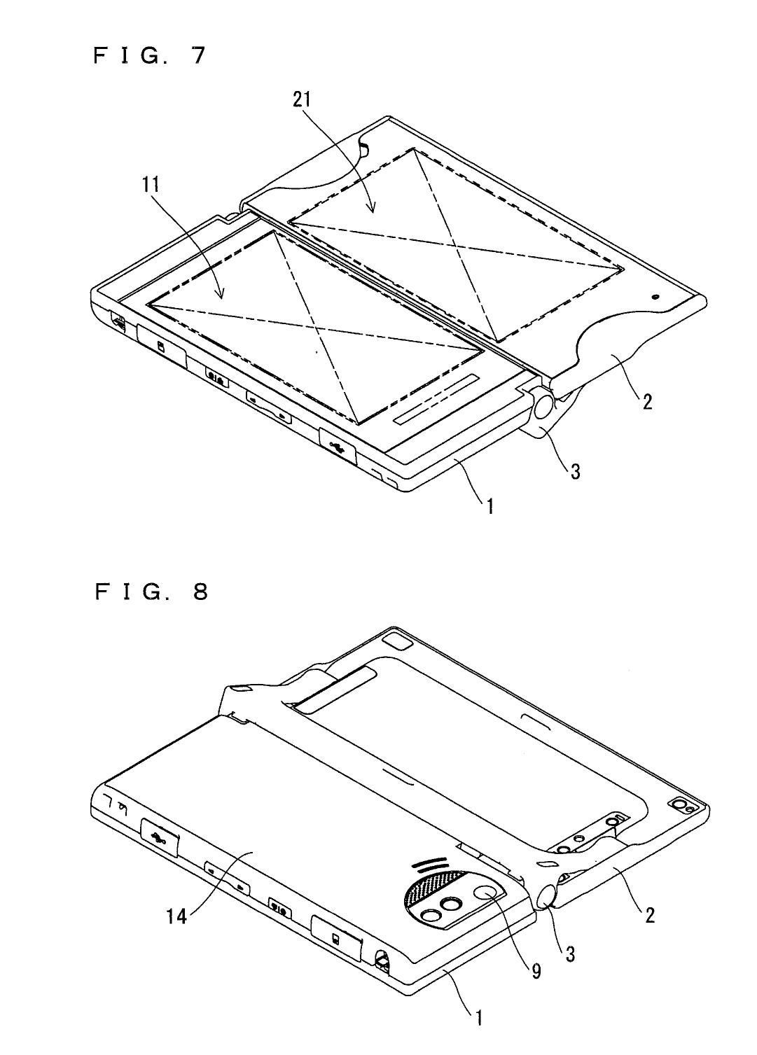

The portable electronic apparatus according to the present invention is capable of being selectively set in four states as follows: a closed state where the first casing 1 is covered at its surface with the rear surface of the second casing 2 and, also, the surface of the second casing 2 is exposed as illustrated in FIG. 1 and FIG. 2; a tilt state where the second casing 2 has been rearwardly moved so that the surfaces of the both the casings 1, 2 are exposed and, also, the surface of the second casing 2 is inclined with respect to the surface of the first casing 1 at an angle of opening which is equal to or more than 90 degrees but less than 180 degrees as illustrated in FIG. 3 and FIG. 4; a first open state where the second casing 2 has been rearwardly rotated so that the surfaces of both the casings 1 and 2 are exposed in the same plane as illustrated in FIG. 5 and FIG. 6; and a second open state where the second casing 2 has been slid toward the first casing 1 in a state where the surfaces of both the casings 1 and 2 are exposed in the same plane as illustrated in FIG. 7 and FIG. 8.

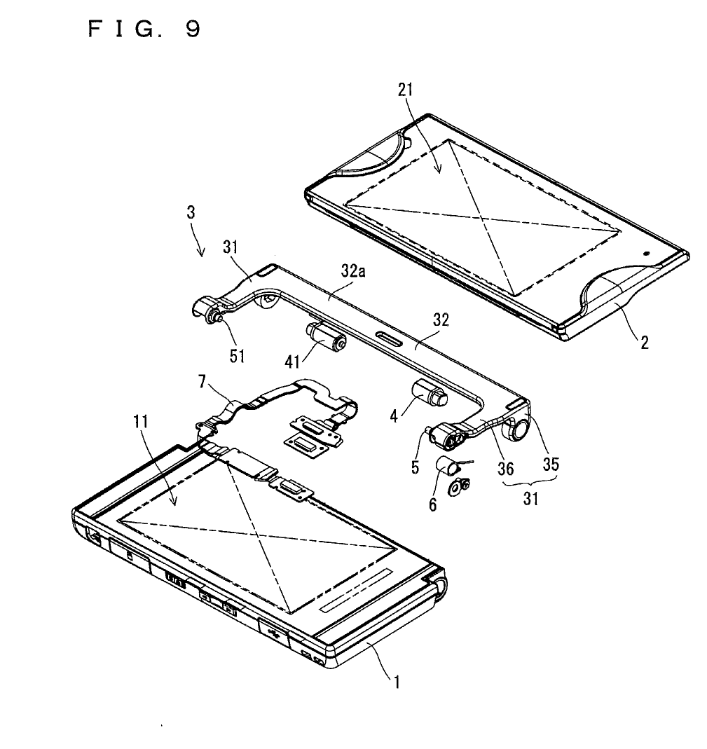

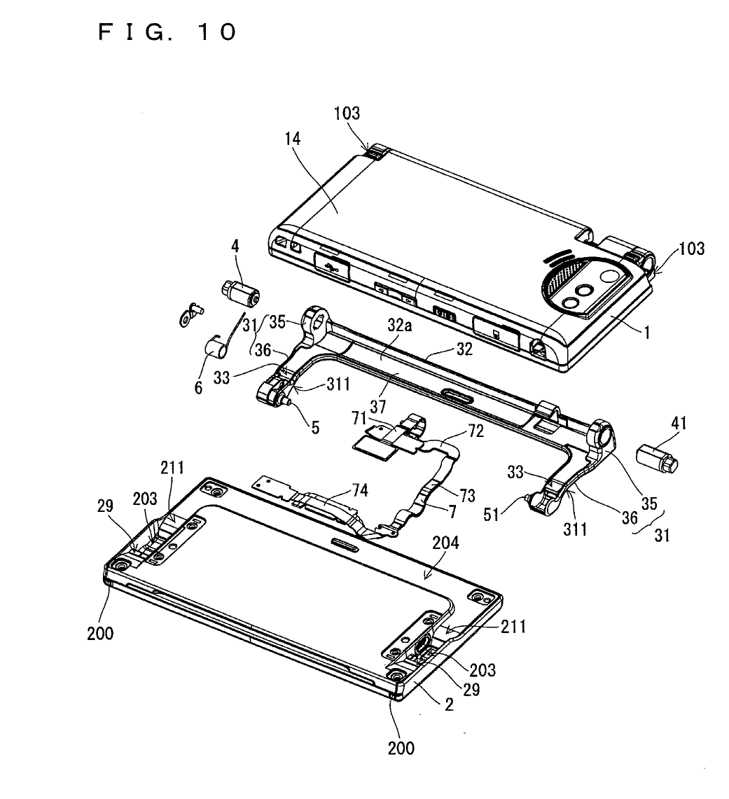

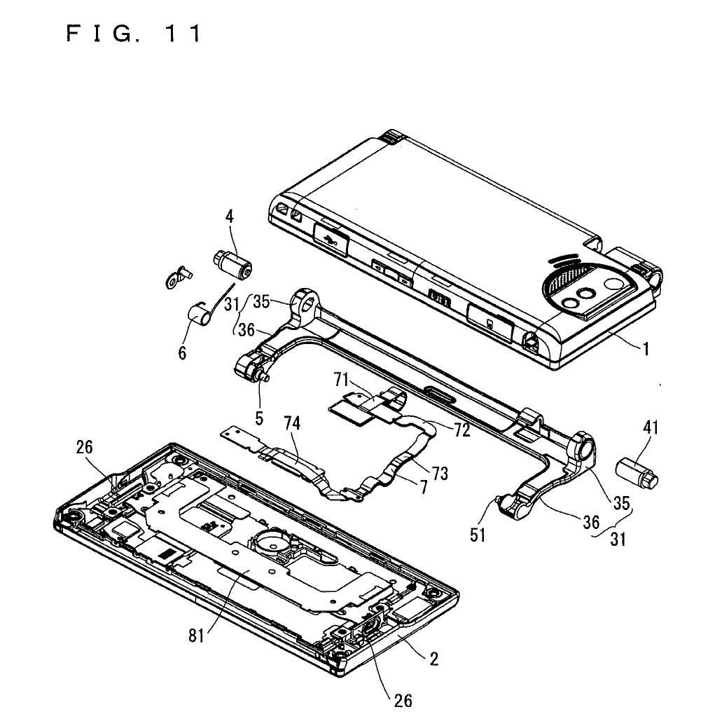

The coupling mechanism 3 which couples the first casing 1 and the second casing 2 to each other includes a U-shaped coupling member 32 constituted by an arm coupling portion 32a extending leftwardly and rightwardly, and a pair of left and right coupling arms 31 and 31 which extend in the forward and rearward directions and protrude from the opposite end portions of the arm coupling portion 32a, as illustrated in FIG. 9 and FIG. 10.

Each coupling arm 31 is of an L type which is bent in an L shape in a plane orthogonal to the display surfaces of both the casings and, also, is constituted by a first arm portion 35 and a second arm portion 36 which intersect with each other at the angular portion of the L shape.

The right coupling arm 31 is coupled, at its base end portion (the base end portion of the first arm portion 35), to the rear end portion of the right side surface of the first casing 1 through a well-known type hinge unit 4 incorporating a spring and a cam mechanism. The left coupling arm 31 is coupled, at its base end portion (the base end portion of the first arm portion 35), to the rear end portion of the left side surface of the first casing 1 through a dummy hinge unit 41 incorporating neither a spring nor a cam mechanism.

Further, the right coupling arm 31 is coupled, at its tip end portion (the tip end portion of the second arm portion 36), to the right end portion of the rear surface of the second casing 2 through a first hinge member 5. The left coupling arm 31 is coupled, at its tip end portion (the tip end portion of the second arm portion 36), to the left end portion of the rear surface of the second casing 2 through a second hinge member 51.

The hinge units 4 and 41 form a first pivot shaft which couples the base end portions of the coupling arms 31 to the first casing 1, while the hinge members 5 and 51 form a second pivot shaft which couples the tip end portions of the coupling arms 31 to the second casing 2, such that the first pivot shaft and the second pivot shaft are parallel to each other.

Further, the second arm portions 36 of the respective coupling arms 31 are provided with abutting surfaces 311 at their portions facing the second casing 2 and, also, the second casing 2 is provided with abutting receiving surfaces 211 to receive the abutting surfaces 311 in the closed state.

The electronic components incorporated in the first casing 1 and the electronic components incorporated in the second casing 2 are connected to each other through a flexible lead 7. The flexible lead 7 extends from the inside of the first casing 1 to the inside of the second casing 2 through the inside of a coupling arm 31. Further, the flexible lead 7 includes a first lead portion 71 housed within the first casing 1, a second lead portion 72 housed within the coupling arm 31, and a third lead portion 73 housed within the second casing 2.

Further, the length of the flexible lead 7 includes minimum necessary leeway which allows the first casing 1 and the second casing 2 to move relative to each other.

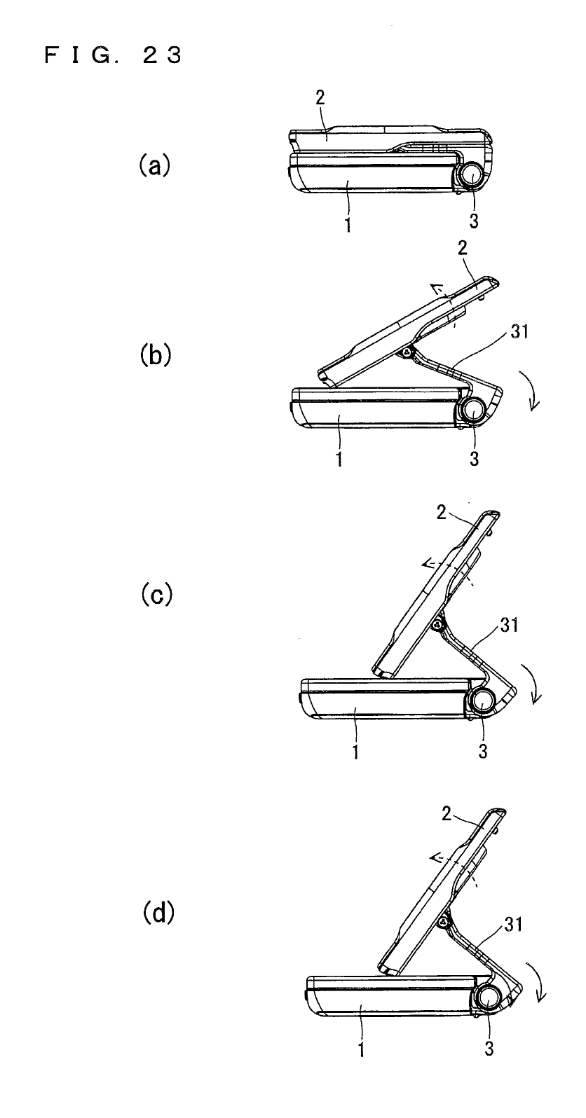

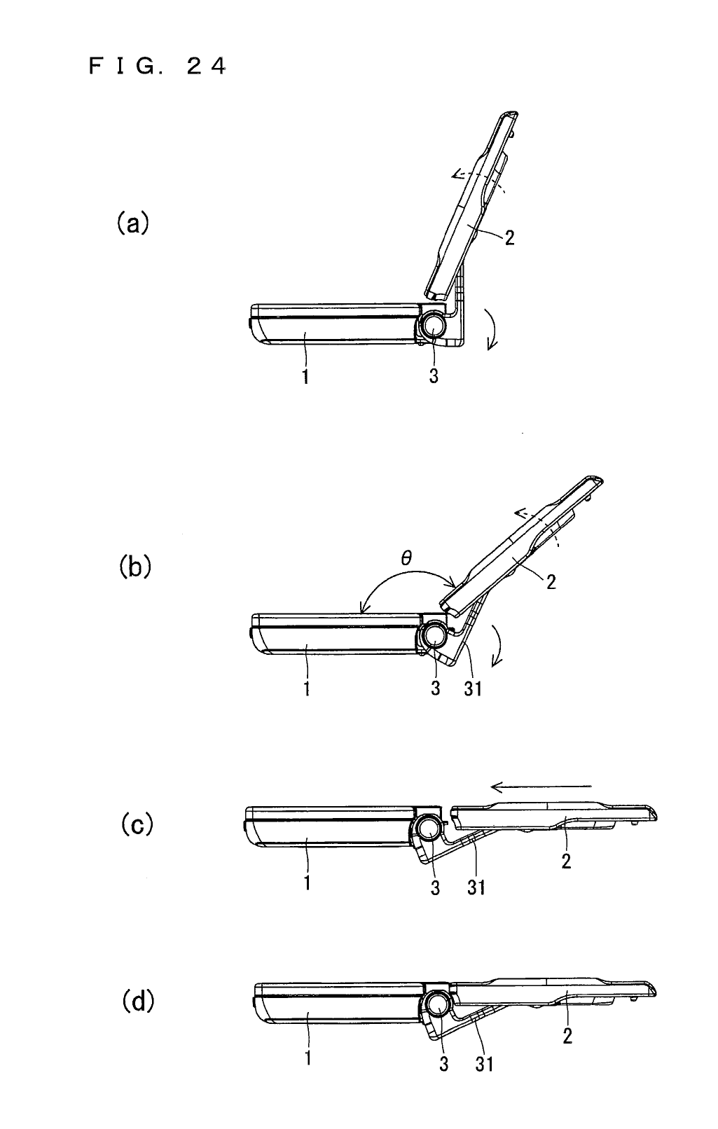

This allows the second casing 2 to perform a series of movements relative to the first casing 1 as illustrated in FIGS. 23A to D and FIGS. 24A to D.

In the tilt state illustrated in FIG. 3 and FIG. 4, the hinge unit 4 softly locks the coupling member 32 with respect to the first casing 1 and, also, biases the coupling member 32 toward the rotational angle of the tilt state, within a certain angle range centered at the rotational angle of the tilt state. Further, the hinge unit 4 biases the coupling member 32 toward the rotational angle of the first open state, within a certain angle range including the rotational angle of the first open state illustrated in FIG. 5 and FIG. 6.

Further, in the first open state illustrated in FIG. 5 and FIG. 6, the coupling member 32 is received by the first casing 1, so that the coupling member 32 is held at the rotational angle of the first open state.

As illustrated in FIG. 9, a torsion spring 6 is mounted in the first hinge member 5 such that it is centered at the rotational shaft (the second pivot shaft) thereof, and the torsion spring 6 biases the second casing 2 in such a direction as to reduce the angle θ of opening in the tilt state illustrated in FIG. 24B.

Further, as illustrated in FIG. 10, the first casing 1 is provided, at the rear end portions of its opposite side surfaces, with housing portions 103 and 103 with concave shapes to house the first arm portions 35 and 35 of the coupling arms 31 and 31 of the coupling member 32.

On the other hand, the second casing 2 is provided, at the opposite side portions of its rear surface, with housing portions 204, 203 and 203 with concave shapes to house the arm coupling portion 37 and the second arm portions 36 and 36 of the coupling member 32.

Further, as illustrated in FIG. 10, both the coupling arms 31 and 31 of the coupling member 32 are provided with respective receiving surfaces 33 for receiving the second casing 2, at their portions facing the second casing 2 and, also, the second casing 2 is provided, at the opposite end portions of its rear surface, with respective sliding surfaces 29 to slidably come into contact with the receiving surfaces 33.

In the tilt state illustrated in FIG. 3 and FIG. 4 and in the first open state illustrated in FIG. 5 and FIG. 6, the sliding surfaces 29 in the second casing 2 come into contact with the receiving surfaces 33 in the coupling arm 31 to receive the rotation of the second casing 2 with respect to the coupling arms 31, so that the attitude of the second casing 2 with respect to the coupling arms 31 is defined in the tilt state and in the first open state.

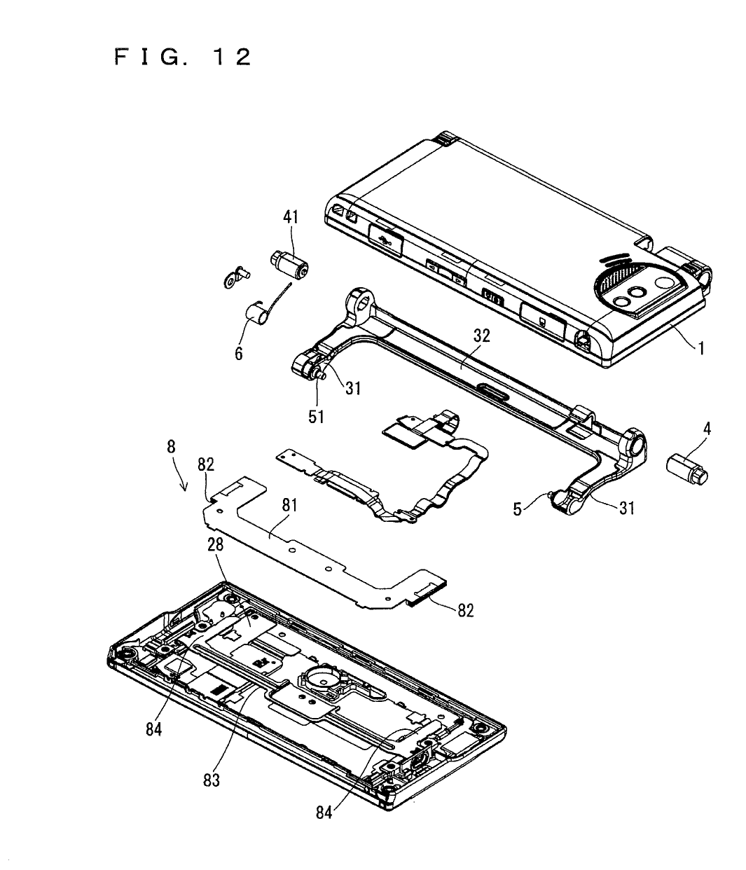

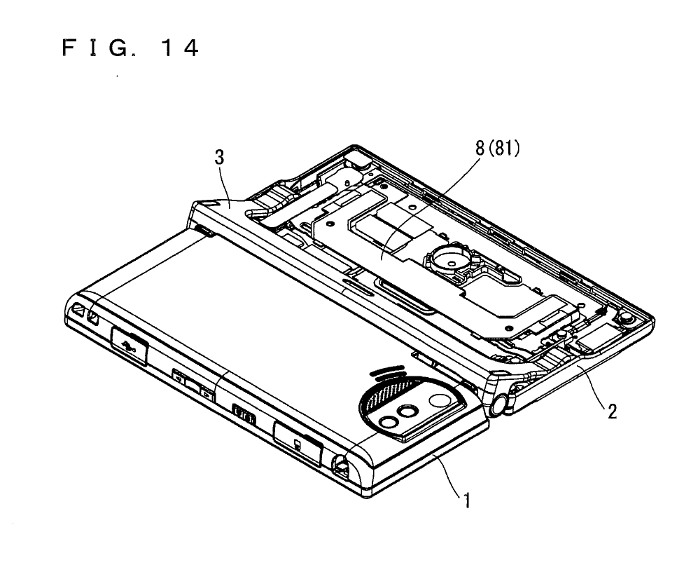

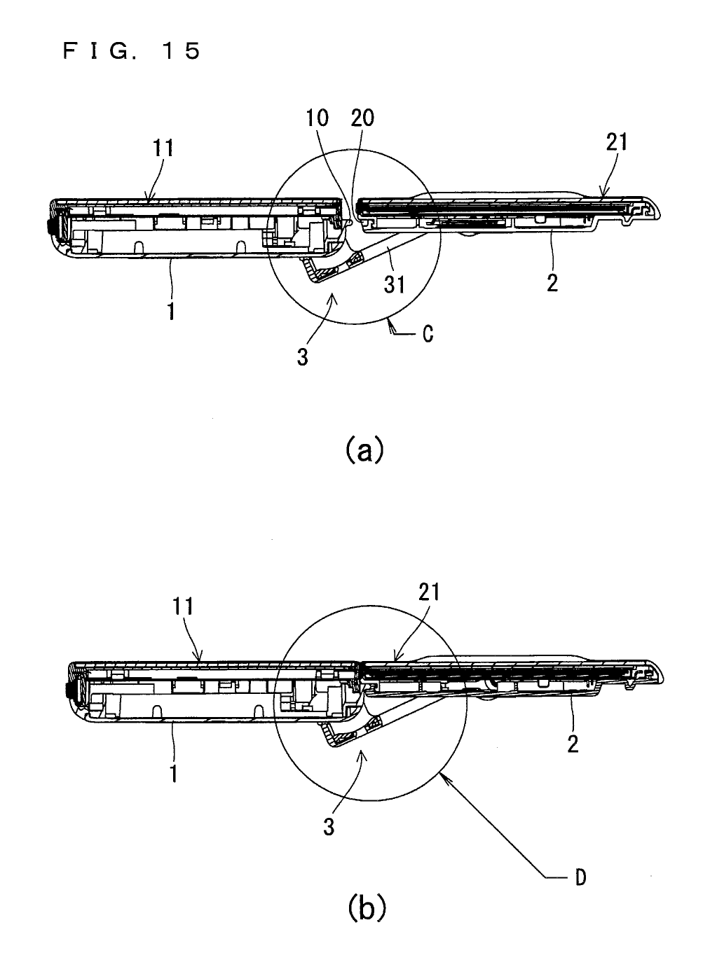

As illustrated in FIG. 12, on a sheet metal member 28 installed inside the second casing 2, there is provided a U-shaped sliding member 83 which is slidable forwardly and rearwardly and, also, there is fixed a U-shaped supporting member 81 such that it covers the sliding member 83 (see FIG. 14).

As illustrated in FIG. 12, the sliding member 83 is provided with arm portions 84 and 84 protruding from its opposite end portions in the left and right sides. Further, slidable guide members 82 and 82 are mounted to the supporting member 81 at its opposite end portions in the left and right sides.

Further, the arm portions 84 and 84 of the sliding member 83 are sandwiched between the sheet metal member 28 and the slidable guide members 82 and 82 of the supporting member 81, so that the sliding of the sliding member 83 in the forward and rearward directions on the sheet metal member 28 is guided.

The first hinge member 5 and the second hinge member 51 which have been described above are pivotally coupled, at their respective tip end portions, to the opposite side portions of the arm portions 84 and 84 of the sliding member 83.

Accordingly, there is structured a sliding mechanism 8 for sliding the second casing 2 in the forward and rearward directions with respect to the arm portions 84 and 84 of the sliding member 83, so that the second casing 2 is enabled to slide forwardly and rearwardly, between the first open state illustrated in FIG. 5 and FIG. 6 and the second open state illustrated in FIG. 7 and FIG. 8.

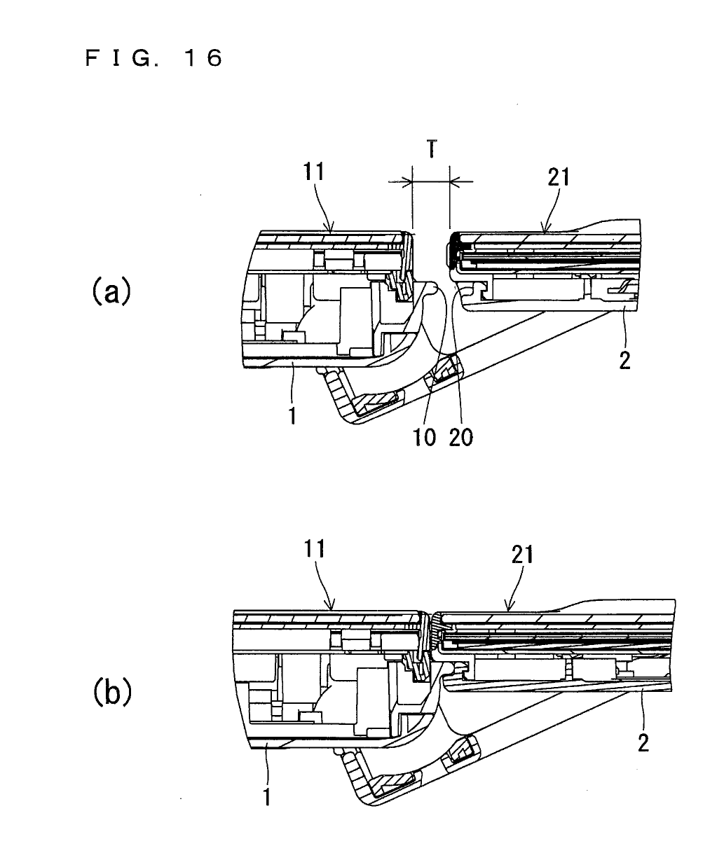

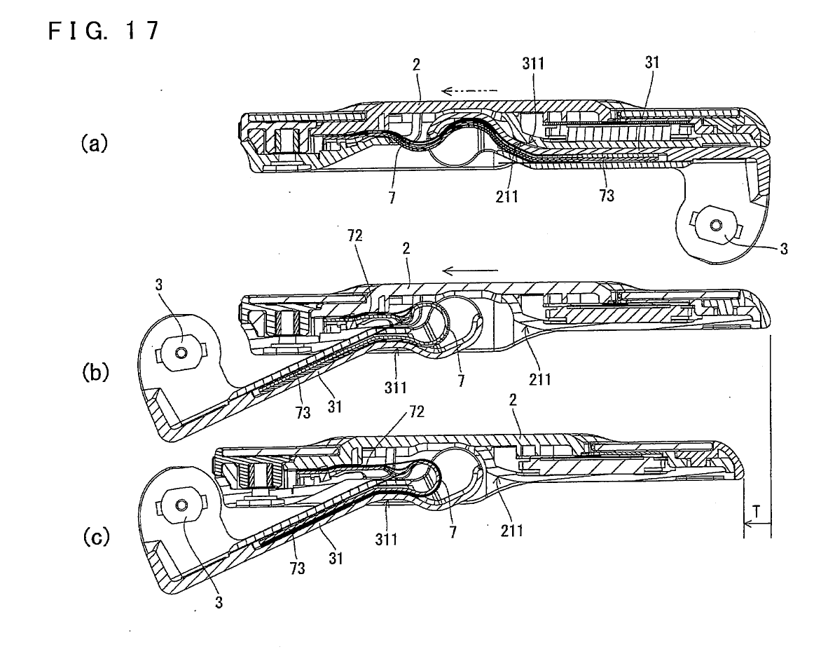

The rear end surface of the first casing 1 and the front end surface of the second casing 2, which are faced to each other in the first open state, are provided with a convex portion 10 and a concave portion 20, respectively, which can be engaged with and disengaged from each other, as illustrated in FIGS. 15A and B and FIGS. 16A and B. In the first open state illustrated in FIG. 15A and FIG. 16A, the convex portion 10 and the concave portion 20 are disengaged from each other, but in the second open state illustrated in FIG. 15B and FIG. 16B, the convex portion 10 and the concave portion 20 are engaged with each other.

As a result thereof, in the second open state illustrated in FIG. 15B and FIG. 16B, the first casing 1 and the second casing 2 are coupled to each other through the engagement between the convex portion 10 and the concave portion 20, so that they are maintained at a state where the first display surface 11 and the second display surface 21 are flushed with each other in the same plane.

In the first open state illustrated in FIG. 15A and FIG. 16A, a gap T with a sufficient size (for example, several millimeters) is provided between the first casing 1 and the second casing 2. However, in the second open state illustrated in FIG. 15B and FIG. 16B, the first casing 1 and the second casing 2 come into contact with each other or are faced to each other with a small interval (for example, 0.1 mm) interposed therebetween.

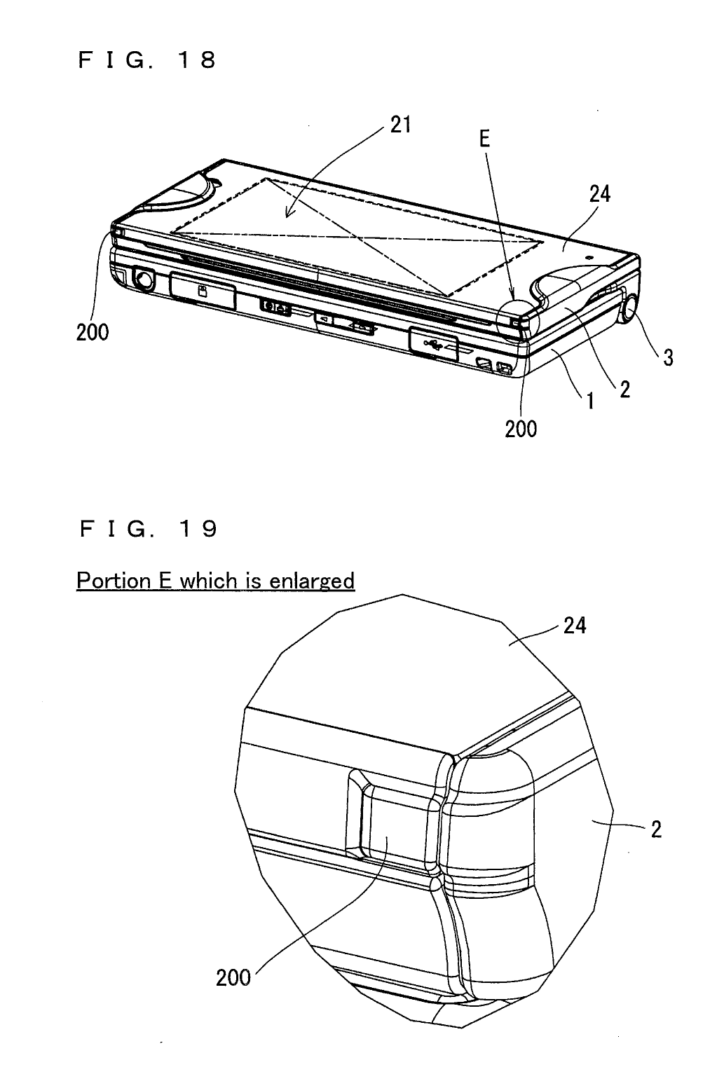

Further, in the portable electronic apparatus, as illustrated in FIGS. 18 to 21, the second casing 2 is provided with a pair of convex portions 200 and 200, at the opposite end portions of its front end surface in the left and right side thereof. The height H of the protrusion of the convex portions 200 is about 0.3 mm.

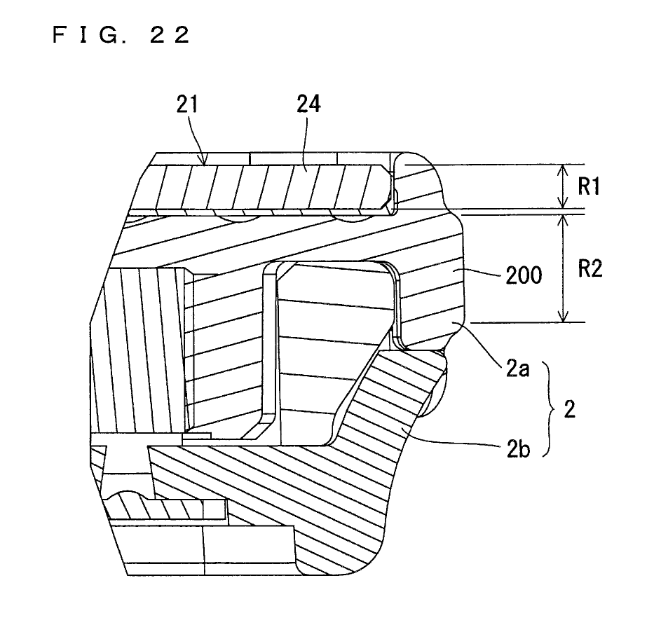

More specifically, as illustrated in FIG. 22, the second casing 2 is constituted by a front-surface casing 2a and a rear-surface casing 2b, and the pair of convex portions 200 and 200 are formed in the front-surface casing 2a, such that, with respect to the glass plate 24 in the front-surface casing 2a, the pair of convex portions 200 and 200 are placed in an area R2 deviated from the thickwise area R1 of the glass plate 24 and, also, with respect to the second display 22, as illustrated in FIG. 20, the pair of convex portions 200 and 200 are placed at positions deviated from the second display 22 in the widthwise direction thereof.

The portable electronic apparatus is capable of being selectively set in four states as follows: the closed state where the first casing 1 and the second casing 2 are overlaid on each other such that only the second display surface 21 is exposed as illustrated in FIG. 1 and FIG. 2; the tilt state where the second casing 2 has been rearwardly moved from the closed state so that both the first display surface 11 and the second display surface 21 are exposed and, also, the second display surface 21 is inclined with respect to the first display surface 11 at an angle of opening which is equal to or more than 90 degrees but less than 180 degrees as illustrated in FIG. 3 and FIG. 4; the first open state where the second casing 2 has been rearwardly rotated from the tilt state so that both the first display surface 11 and the second display surface 21 are exposed in the same plane as illustrated in FIG. 5 and FIG. 6; and the second open state where the second casing 2 has been slid toward the first casing 1 from the first open state, and both the display surfaces 11 and 21 are exposed in the same plane at positions where the first display surface 11 and the second display surface 21 are closer to each other as illustrated in FIG. 7 and FIG. 8.

In the closed state illustrated in FIG. 1 and FIG. 2, the first arm portions 35 and 35 of the coupling arms 31 and 31 are housed in the housing portions 103 and 103 in the first casing 1 illustrated in FIG. 10 and, also, the arm coupling portion 37 and the second arm portions 36 and 36 of the coupling member 32 are housed in the housing portions 204, 203 and 203 in the second casing 2, so that the coupling mechanism 3 is not protruded from the opposite side surfaces and the rear end surfaces of both the casings 1 and 2 and, thus, the entire apparatus is compacted.

Further, in the closed state, as illustrated in FIG. 18, the front end surface of the first casing 1 and the front end surface of the second casing 2 are aligned, and the convex portions 200 and 200 are protruded forwardly from the front end surfaces of both the casings 1 and 2.

In any of the tilt state illustrated in FIG. 3, the first open state illustrated in FIG. 5 and the second open state illustrated in FIG. 7, the coupling mechanism 3 is hidden substantially in its entirety behind the rear surfaces of both the casings 1 and 2 and, therefore, it is hard to view the protruding portion of the coupling mechanism 3 along an usual user's line of sight (an arrow S in FIG. 1).

Further, in the second open state, the first arm portions 35 and 35 of the coupling arms 31 and 31 in the second casing 2 are housed in the housing portions 103 and 103 in the first casing 1 illustrated in FIG. 10 and, further, the convex portions 200 and 200 in the second casing 2 are also housed therein.

As illustrated in FIGS. 23A to D and FIGS. 24A to D, in processing for shifting the portable electronic apparatus from the closed state to the second open state through the tilt state and the first open state, if the second casing 2 is pushed rearwardly to be slightly moved from the closed state illustrated in FIG. 18A, the second casing 2, thereafter, is rotated in the counterclockwise direction as indicated by a broken-line arrow due to the biasing by the torsion spring 6 and, along therewith, the coupling arms 31 are rotated in the clockwise direction as indicated by a solid-line arrow, as illustrated in B to D in the same figure.

Thus, the second casing 2 is rearwardly moved, while the second display surface 21 is kept oriented upwardly or obliquely upwardly.

Further, at a time point slightly after the state of FIG. 23D, the coupling arms 31 are further rotated in the clockwise direction, due to the biasing by the hinge unit 4, as in FIG. 24A, and, then, are softly locked at the rotational angle of the tilt state as in B in the same figure. Further, the second casing 2 is rotated in the counterclockwise direction due to the biasing by the torsion spring 6 and is held at the attitude in the tilt state illustrated in FIG. 24B since the sliding surfaces 29 comes into contact with the receiving surfaces 33 in the coupling arms 31.

Accordingly, if the user merely pushes the second casing 2 rearwardly at the closed state illustrated in FIG. 23A to slightly move it, then, the second casing 2 automatically moves to the tilt state illustrated in FIG. 24B.

Next, if the second casing 2 is pushed rearwardly to slightly rotate the coupling arms 31 in the clockwise direction in the tilt state illustrated in FIG. 24B, then the coupling arms 31 are rotated to the rotational angle of the first open state illustrated in FIG. 24C due to the biasing by the hinge unit 4 and are received by the first casing 1 at this rotational angle, while the sliding surfaces 29 in the second casing 2 are kept in contact with the receiving surfaces 33 in the coupling arms 31.

Along with this rotation of the coupling arms 31, the second casing 2 is rearwardly rotated and, finally, the first display surface 11 and the second display surface 21 are aligned in the same plane.

Further, if the second casing 2 is pulled toward the first casing 1 in the first open state illustrated in FIG. 24C, the sliding surfaces 29 in the second casing 2 slide on the receiving surfaces 33 in the coupling arms 31, so that the second casing 2 horizontally moves to a second open position illustrated in FIG. 24D and, finally, comes into contact with the first casing 1.

As a result thereof, as illustrated in FIG. 7, the first display surface 11 and the second display surface 21 get closer to each other, so that both the display surfaces 11 and 21 form a single large screen.

In the second open state, as illustrated in FIG. 15B, the convex portion 10 in the first casing 1 and the concave portion 20 in the second casing 2 are engaged with each other, so that both the casings 1 and 2 are coupled to each other. Accordingly, even if an operation for strongly touching the second display surface 21 is performed in this state, the second casing 2 is maintained at a certain attitude with respect to the first casing 1.

FIGS. 17A to C illustrate states of deformations and bendings of the flexible lead 7, during processing for transitions from the closed state to the second open state through the first open state.

In the closed state illustrated in FIG. 17A, as described above, the abutting surfaces 311 formed in the second arm portions 36 of the coupling arms 31 and the abutting receiving surfaces 211 formed in the second casing 2 come into contact with each other, so that the second casing 2 is prevented from sliding in the direction indicated by a two-dot-chain line arrow.

Next, in the first open state illustrated in FIG. 17B, along with the rotation of the coupling arms 31, the flexible lead 7 is largely deformed and bent, between the first lead portion 72 and the third lead portion 73.

Further, if the second casing 2 is slid forwardly leftwardly in the figure by a distance T from the state illustrated in FIG. 17B as indicated by an arrow in the figure, this realizes the second open state illustrated in FIG. 17C. During this processing, the flexible lead 7 is forwardly displaced, by increasing the curvature in its bending portion between the second lead portion 72 and the third lead portion 73.

In the portable electronic apparatus, in the closed state illustrated in FIG. 17A, the second casing 2 is prevented from moving in the direction indicated by the chain-line arrow in the figure, which enables reduction of the length of the flexible lead 7 by a length corresponding to leeway which would be required to be provided in the flexible lead 7 if the second casing 2 were allowed to slide through an operation of the slide mechanism 8.

This enables forming the flexible lead 7 by determining the length thereof in consideration of only the deformations and bendings of the flexible lead 7 along with the rotation of the coupling arms 31 illustrated in FIGS. 17A to C. This enables suppressing the looseness of the flexible lead 7 in the closed state illustrated in FIG. 17A to a minimum necessary amount.

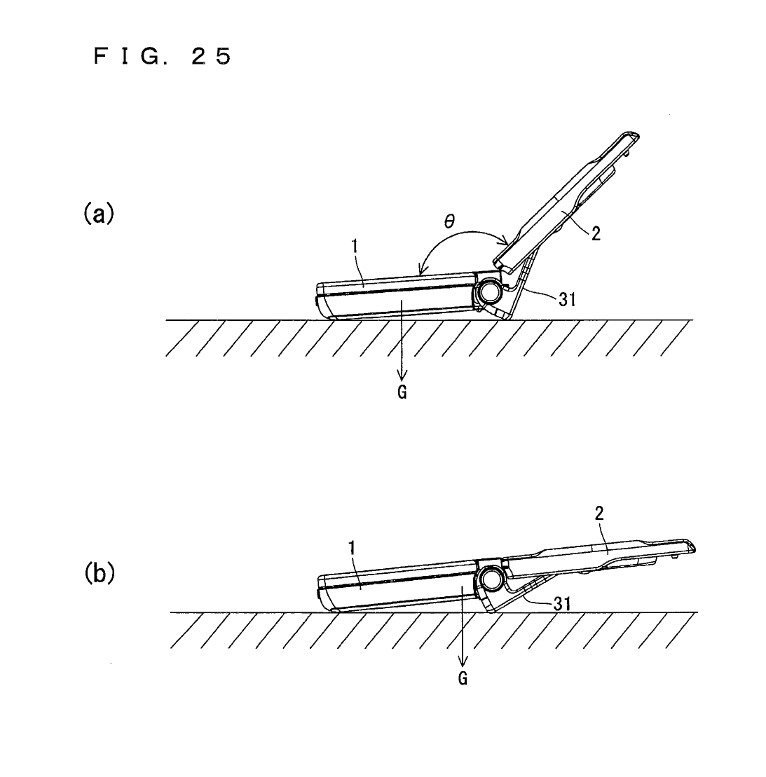

When the portable electronic apparatus is placed on a desk in the tilt state as illustrated in FIG. 25A or when it is placed on a desk in the second open state as illustrated in FIG. 25B, the angular portions of the coupling arms 31 are protruded from the rear surface of the first casing 1, so that the front end portion of the first casing 1 and the angular portions of the coupling arms 31 are grounded.

In this case, the L shape of the coupling arms 31 and the placement of the components with respect to the first casing 1 and the second casing 2 are designed, such that the center of gravity G is positioned in the firs casing 1 side with respect to the grounded points of the coupling arms 31 as illustrated in the figure, in any state. This enables stabilization of the attitudes of both the casings 1 and 2.

Accordingly, when it is placed on a desk in the tilt state as illustrated in FIG. 25A, it is possible to operate the touch panel 13 in the first casing 1 in the front side, while viewing the display 12 in the second casing 2 in the rear side.

Further, when it is placed on a desk in the second open state as illustrated in FIG. 25B, both the display surfaces 11 and 21 take such attitudes as to be slightly oriented toward the user depending on the amount of the protrusion of the angular portions of the coupling arms 31 and, for example, both the display surfaces 11 and 21 form a single screen, which enables viewing images on the large screen. In this case, both the display surfaces 11 and 21 are sufficiently close to each other, which enables displaying images with substantially no discontinuities, on both the display surfaces 11 and 21.

Furthermore, with the portable electronic apparatus, in the event that the apparatus is fallen onto a floor surface, if the apparatus, during the falling, takes such an attitude that the front end surface of the second casing 2 faces downwardly, any one convex portion 200, out of the pair of the convex portions 200 and 200 formed in the front end surface, impinges on the floor surface at first and, immediately thereafter, the other convex portion 200 impinges on the floor surface.

In this case, as illustrated in FIG. 20, the second display 22 is placed such that it is as close to the front end surface of the second casing 2 as possible, and the glass plate 24 is placed such that it covers the second display 22. Accordingly, there is a significantly small distance between the front end surface of the glass plate 24 and the front end surface of the second casing 2. Thus, if an impulsive force acts on the front end surface of the second casing 2, this impulsive force may be transmitted to the glass plate 24, thereby causing a fracture of the glass plate 24.

However, in the portable electronic apparatus, the pair of the convex portions 200 and 200 are placed at positions which are deviated from the glass plate 24 in the second casing 2 in the thickwise direction and, also, are deviated from the second display 22 in the widthwise direction, so that these convex portions 200 exert their shock absorption effects depending on their height. Therefore, in comparison with cases where an apparatus impinges on a floor surface at its front end surface provided with no such convex portions 200, it is possible to largely reduce the impulsive force acting on the second display 22 and on the glass plate 24 covering the second display 22.

As a result thereof, it is possible to suppress the occurrence of fractures of the second display 22 and the glass plate 24 due to effects of such impulsive forces.

Further, an impulsive force may act on the glass plate 16 in the first casing 1 due to falling thereof. However, in the closed state, the first casing 1 is covered, at its rear end surface, with the coupling member 32 illustrated in FIG. 9, which can alleviate the impulsive force acting on the glass plate 16 in the first casing 1.

Further, the structures of the respective components of the present invention are not limited to those in the aforementioned embodiments, and various changes can be made thereto within the technical scope defined in the claims. For example, instead of the glass plates 16 and 24, it is possible to employ light-transparent plates made of resins, for example.

What is claimed is:

1. A portable electronic apparatus comprising:
a first casing having a first display in its surface;
a second casing having a second display in its surface; and
a coupling mechanism adapted to couple the first casing and the second casing to each other to take at least two states which are a closed state where the first display in the first casing is covered with a rear surface of the second casing and, also, the second display in the second casing is exposed, and an open state where the second casing has been moved from the closed state so that the displays in both the casings are exposed in the same plane;
wherein the second casing is provided with at least a single convex portion which faces the first casing in the open state and, also, protrudes forwardly from a front end surface of the first casing in the closed state, on its front end surface which aligns with the front end surface of the first casing in the closed state.

2. The portable electronic apparatus according to claim 1, wherein
the convex portion is provided at opposite end portions of the front end surface of the second casing.

3. The portable electronic apparatus according to claim 1, further comprising a light transparent plate adapted to cover a surface of the second display,
wherein the convex portion is formed at a position deviated from the light transparent plate in a thickwise direction of the light transparent plate.

4. The portable electronic apparatus according to claim 1, wherein
the convex portion is formed at a position deviated from the second display in a widthwise direction of the second display.
